(19) United States
(12) Patent Application Publication
(10) Pub. No.: US 2026/0190210 A1
(43) Pub. Date: Jul. 2, 2026

(54) COOLING SYSTEM

(71) Applicant: Microsoft Technology Licensing, LLC, Redmond, WA (US)

(72) Inventors: Alexis Grace SCHUBERT, Seattle, WA (US); Oscar FARIAS MOGUEL, Seattle, WA (US); Christy Felix Pradeep ANTONY, Mississauga (CA); Dennis TRIEU, Calgary (CA); David William MAYER, Woodinville, WA (US); Kaixuan HU, Fremont, CA (US)

(21) Appl. No.: 19/004,950

(22) Filed: Dec. 30, 2024

(51) Int. Cl. H05K 1/02; H05K 7/20

(52) U.S. Cl. CPC H05K 1/0203; H05K 7/20327; H05K 7/20809; H05K 2201/064

(57) ABSTRACT

A system includes a cooling unit and a thermally conductive structure. The cooling unit and thermally conductive structure define a gap between the cooling unit and the thermally conductive structure. The thermally conductive structure includes an appendage extending from the thermally conductive structure across the gap to the cooling unit for thermal conduction with the cooling unit. The gap is sized to receive a printed circuit board and attached components.

### BACKGROUND

Cooling electrical components in a server environment is challenging due to dimensional constraints. Traditional methods of cooling may not be possible with servers being stacked closely together and heat generating components positioned on the top and bottom surfaces of a printed circuit board. Air cooling may not be available because of the lack of open space through which air can flow. Traditional heat sinks and cooling fins may not be used because they would occupy space that needs to be devoted to other resources.

Other cooling methods including immersion in a cooling fluid may be available but have other challenges. For example, loss of coolant, contamination of the coolant, costs associated with immersion infrastructure, and complications to server servicing models, are some concerns that arise with immersion cooling techniques. Consequently, immersion cooling may increase the difficulty of replacement and repair of servers.

### BRIEF SUMMARY

In some aspects, the techniques described herein relate to a system. The system includes a cooling unit and a thermally conductive structure defining a gap between the cooling unit and the thermally conductive structure (e.g., a surface requiring cooling). The thermally conductive structure includes an appendage extending from the thermally conductive structure across the gap to the cooling unit for thermal conduction with the cooling unit. The gap is sized to receive a printed circuit board and attached components.

In some aspects, the techniques described herein relate to a method. The method includes placing a printed circuit board on a thermally conductive structure. The thermally conductive structure engages a bottom surface component attached to a bottom surface of the printed circuit board to create a thermally conductive connection between the bottom surface component and thermally conductive structure. The thermally conductive structure includes an appendage extending from the thermally conductive structure past the printed circuit board. The method further includes positioning a cooling unit on a top surface component attached to a top surface of the printed circuit board and the appendage to create a thermally conductive connection between the cooling unit and the top surface component and to create a thermally conductive connection between the cooling unit and the appendage.

In some aspects, the techniques described herein relate to a server rack. The server rack includes a power bus, a data connection, and a cooling fluid manifold. The server rack does not include an air moving system. The server rack includes a server. The server is connected to the power bus, the data connection, and the cooling fluid manifold. The server includes a cooling unit including a cooling fluid conduit and an external connection port fluidly connected to the cooling fluid conduit. The external connection port is connected to the cooling fluid manifold. The server also includes a printed circuit board including a top surface and a bottom surface. The printed circuit board is electrically connected to the power bus and the data connection. A plurality of electrical components are attached to the top surface and the bottom surface of the printed circuit board. The server also includes a thermally conductive structure including a substantially planar body and an appendage extending from the substantially planar body across the printed circuit board to the cooling unit for thermal conduction with the cooling unit.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and advantages of embodiments of the disclosure will be set forth in the description which follows, and in part will be obvious from the description, or may be learned by the practice of such embodiments. The features and advantages of such embodiments may be realized and obtained by means of the instruments and combinations particularly pointed out in the appended claims. These and other features will become more fully apparent from the following description and appended claims, or may be learned by the practice of such embodiments as set forth hereinafter.

### BRIEF DESCRIPTION OF DRAWINGS

In order to describe the manner in which the above-recited and other features of the disclosure may be obtained, a more particular description will be rendered by reference to specific implementations thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations will be described and explained with additional specificity and detail through the use of the accompanying drawings in which:

FIG. 1 is a side view of a schematic diagram of a server rack according to at least one embodiment of the present disclosure;

FIG. 2 is a side view of a schematic diagram of a cooling system containing a printed circuit board and attached components according to at least one embodiment of the present disclosure;

FIG. 3 is a side view of a schematic diagram of a cooling system according to at least one embodiment of the present disclosure;

FIG. 4 is a side view of a schematic diagram of a cooling system containing a printed circuit board and attached components according to at least one embodiment of the present disclosure;

FIG. 5 is a side view of a schematic diagram of a cooling system according to at least one embodiment of the present disclosure;

FIG. 6A is a top view of a schematic diagram of a cooling unit of a cooling system according to at least one embodiment of the present disclosure;

FIG. 6B is a top view of a schematic diagram of a printed circuit board positioned on a thermally conductive structure;

FIG. 6C is a top view of a schematic diagram of a thermally conductive structure;

FIG. 7A is a side view of a schematic diagram of a cooling system according to at least one embodiment of the present disclosure;

FIG. 7B is a top view of a schematic diagram of a printed circuit board positioned on a thermally conductive structure;

FIG. 8 is a side view of a schematic diagram of a cooling system according to at least one embodiment of the present disclosure; and

FIG. 9 is a flow chart illustrating a method according to at least one embodiment of the present disclosure.

### DETAILED DESCRIPTION

This disclosure generally relates to systems and methods of cooling electrical components. Printed circuit boards with processors may use vertical power delivery, instead of lateral power delivery, to reduce resistive power losses through the printed circuit board. Vertical power delivery involves components on the bottom surface of the printed circuit board, underneath a processor. Components involved in power conditioning and delivery may be cooled and may restrict heat transfer from the processor from exiting the backside of the printed circuit board. These components are also generating their own heat and so can raise the temperature of the processor and other electrical components on the top surface of the printed circuit board. Restricted heat dissipation may introduce reliability issues for the printed circuit board and all of the electrical components attached to the printed circuit board.

In many applications, the height above and below a processor is constrained by the height allowed for one server. Increasing the height above and below a processor may decrease the number of servers that may be placed in a rack, datacenter, or graphics processing unit pod. As disclosed herein, the embodiments of the present disclosure provide solutions that have a reduced height, provide cooling to top surface and bottom surface electrical components, and reduce the risk of high temperatures occurring in the ball grid array under a processor. The embodiments discussed provide cooling to top and bottom components on a printed circuit board in an environment where air cooling is limited.

Electrical components include processors, memory devices, power conditioning devices, capacitors, resistors, etc. A processor may be a general-purpose single or multi-chip microprocessor (e.g., an Advanced RISC (Reduced Instruction Set Computer) Machine (ARM)), a special purpose microprocessor (e.g., a digital signal processor (DSP)), an artificial intelligence accelerator, an auxiliary processing unit (XPU), a graphics processing unit (GPU), a central processing unit (CPU), a microcontroller, a programmable gate array, etc. A printed circuit board may include a single processor or a combination of processors (e.g., an ARM and DSP).

A memory device is an electronic component capable of storing electronic information. For example, a memory device may be random access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM) memory, registers, and so forth.

To provide cooling to the top surface and bottom surface electrical components attached to a printed circuit board, an active cooling unit is positioned to engage the top surface electrical components. The cooling unit may include a thermally conductive frame that supports a cooling fluid conduit. In this configuration, cooling fluid is moved through the cooling fluid conduit from a source of cooling fluid and directed over the top of electrical components attached to the top surface of the printed circuit board. The cooling fluid may be a water-based mixture and/or other coolant. The cooling fluid may be single phase, where the fluid does not change phase as it removes heat from the components, may be two-phase, where it boils while removing heat, may include multiphase materials, or may include combinations thereof.

A thermally conductive structure is positioned to engage the bottom surface electrical components attached to the printed circuit board. The thermally conductive structure includes an appendage extending across the printed circuit board to the cooling unit for thermal conduction with the cooling unit. The thermally conductive structure is made of materials with high thermal conductivity and may include a substantially planar body that engages the bottom surface electrical components to provide heat transfer and cooling to the bottom surface electrical components. The thermally conductive structure may include heat pipes, vapor chambers, and thermosiphons to increase its ability to conduct heat away from the bottom surface electrical components. Further, the thermally conductive structure may be relatively thin while providing the thermal conduction to cool one or more of the bottom surface electrical components.

With the cooling unit providing cooling above and the thermally conductive structure conducting heat away from the bottom surface electrical components and up to the cooling unit, a cooling “sandwich” is provided that wraps around the printed circuit board to cool the highest-power electrical components or most, if not all, of the electrical components on the printed circuit board. In some configurations, cutouts in the printed circuit board may be included for one or more appendages to extend past the printed circuit board to the cooling unit.

In one embodiment, the appendage may include a condensing chamber positioned near the interface between the thermally conductive structure and the cooling device. The condensing chamber may condense a working fluid that flows down to the body of the thermally conductive structure to be boiled into a vapor by the heat from the bottom surface electrical components. This configuration provides efficient heat transfer in a very small conductive footprint between the cooling unit and the thermally conductive structure.

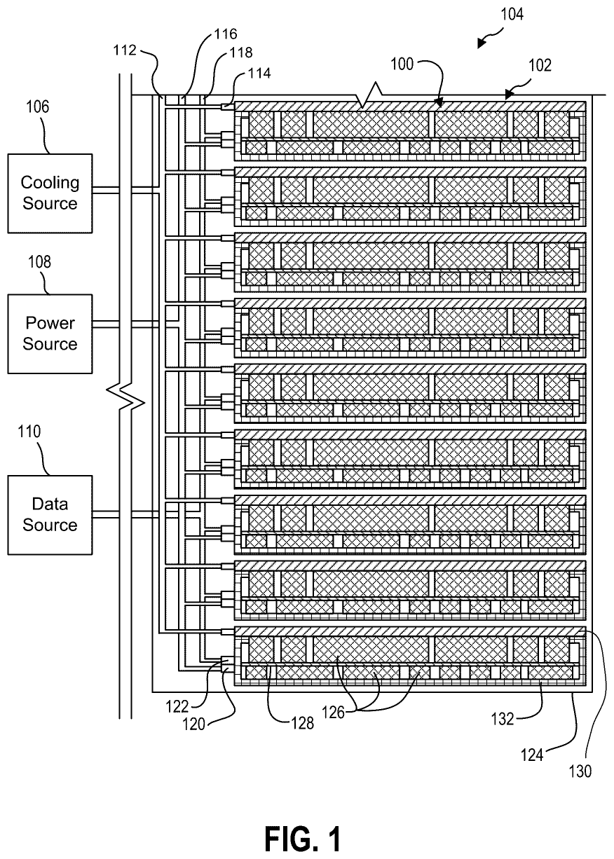

FIG. 1 is a side view of a schematic diagram of a cooling system 100 used in the servers 102 of a server rack 104 according to one or more embodiments. As shown, the server rack 104 is connected to a cooling source 106, a power source 108, and a data source 110. The cooling source 106 provides cooling fluid to the server rack 104.

The cooling source 106 is a system for cooling and pumping cooling fluid into the server rack 104. As cooling fluid moves into the server rack 104, the cooling fluid is distributed to the servers 102 by a cooling fluid manifold 112. The cooling fluid manifold 112 is a system that distributes cooling fluid within the server rack 104. The cooling fluid manifold 112 may be a manifold or a series of valves and piping. The cooling fluid manifold 112 is connected to the servers 102 by an external connection port 114. The external connection port 114 is a device that provides a fluid connection to the cooling fluid manifold 112 allowing access by the server 102 to the cooling source 106. The external connection port 114 may be quick disconnect couplers, threaded couplings, or other devices that provide a fluid connection between the servers 102 and the cooling source 106.

The power source 108 provides electrical power to the servers 102 and server rack 104 and may be an electrical connection to the electrical grid, a solar array, a wind farm, or other electrical generator. Electrical power is distributed in the server rack 104 by a power bus 116 to the servers 102 via an electrical connector 120.

The data source 110 is a connection to a computer network, the cloud, or the internet. A “network” may generally be defined as one or more data links that enable the transport of electronic data between computer systems and/or modules, engines, and/or other electronic devices. The data source 110 is connected to a data connection 118 within the server rack 104. The data connection 118 distributes data between the data source 110 and the servers 102 in the server rack 104. The servers 102 are connected to the data connection 118 via a data connector 122.

As shown, the server rack 104 includes a rack 124 supporting a plurality of servers. The server rack 104 does not include an immersion cooling system. Instead, the servers 102 include a cooling system 100. In some embodiments, the server rack 104 may include an air cooling system. In some embodiments, the server rack 104 may not include an air-cooling system. For example, the server rack 104 may rely solely on the cooling system 100 of the one or more servers 102. In other words, a majority of the cooling provided to the server rack, in some embodiments, comes from the cooling system 100 of the one or more servers and not from an air-cooling system of the server rack 104. In another embodiment, any air-cooling system may provide less than 50%, less than 40%, less than 30%, less than 20%, less than 15%, less than 10%, less than 5%, less than 4%, less than 3%, less than 2%, less than 1.5%, less than 1%, less than 0.75%, less than 0.5%, less than 0.25%, less than 0.20%, less than 0.15%, less than 0.10%, less than 0.05%, less than 0.01%, or 0%.

The cooling system 100 includes a cooling unit 130 and a thermally conductive structure 132. The cooling unit 130 allows cooling fluid to circulate adjacent a plurality of electrical components 126 attached to a top surface of a printed circuit board 128. The thermally conductive structure 132 wraps around a bottom surface of the printed circuit board 128. The thermally conductive structure 132 engages the plurality of electrical components 126 attached to the bottom surface of a printed circuit board 128 to conduct heat away and up to the cooling unit 130.

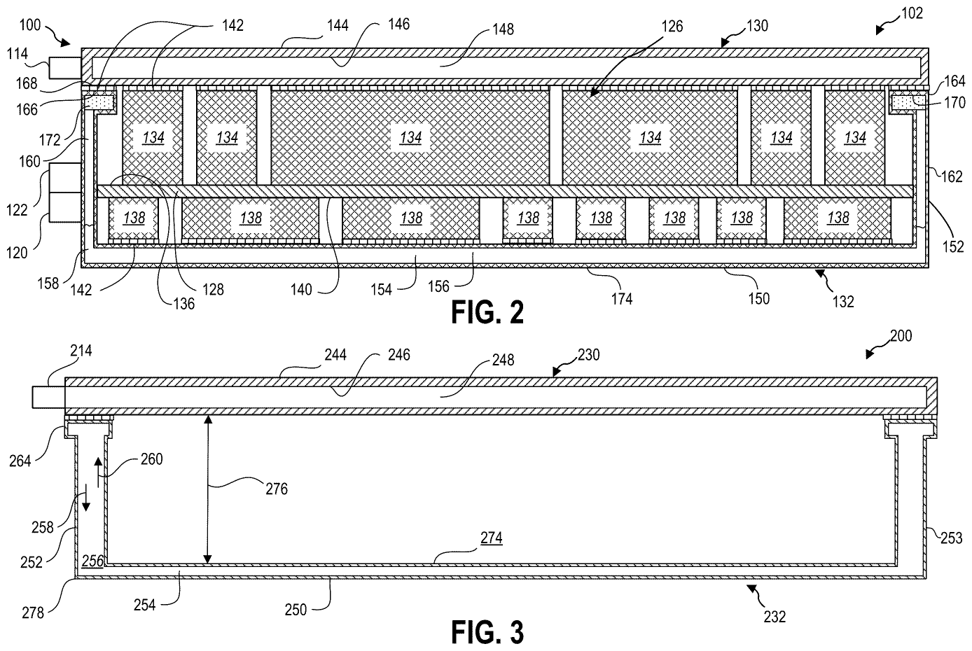

FIG. 2 is a side view of a schematic diagram of the server 102. The cooling system 100 contains the printed circuit board 128 and attached electrical components 126. The electrical components 126 include top surface electrical components 134 attached to a top surface 136 of the printed circuit board 128 and bottom surface electrical components 138 attached to a bottom surface 140 of the printed circuit board 128. The server 102 includes an electrical connector 120 that provides electrical power to the electrical components 126 and a data connector 122 that provides a data connection to select electrical components 126.

A conductive material 142 may be placed on top of the top surface electrical components 134 and on the bottom of the bottom surface electrical components 138. The conductive material 142 is a thermally conductive material such as a thermal pad and/or a thermal paste that is used to ensure a thermal connection is made between components and parts of the cooling system 100.

As shown, the cooling system 100 includes the cooling unit 130 and the thermally conductive structure 132. The cooling unit 130 includes the external connection port 114, a frame 144, and a cooling fluid conduit 146 that is in fluid communication with the external connection port 114. When connected to a source of cooling fluid such as the cooling source 106 (shown in FIG. 1), the cooling fluid conduit 146 is filled with cooling fluid 148 that follows cooling fluid conduit 146 through the cooling unit 130. The external connection port 114 includes an inlet and an outlet. As the cooling fluid 148 moves through the cooling fluid conduit 146, the cooling fluid 148 absorbs heat from and cools the frame 144 of the cooling unit 130 until the higher temperature cooling fluid 148 exits the outlet of the external connection port 114. When disconnected from a source of cooling fluid, a valve in the external connection port 114 closes to retain cooling fluid 148 in the cooling fluid conduit 146. This feature may reduce the potential for spills of cooling fluid while removing a server 102 from a server rack 104 (shown in FIG. 1). The cooling fluid 148 may include water, coolant (e.g., propylene glycol), a refrigerant, other cooling fluids, or mixtures thereof.

The thermally conductive structure 132 includes a substantially planar body 150 and appendages 152. The substantially planar body 150 extends along the bottom of the bottom surface electrical components 138 to provide conductive cooling by conducting heat from the bottom surface electrical components 138 to the cooling unit 130. The substantially planar body 150 may include cutouts and different surface elevations to accommodate different heights of the bottom surface electrical components 138 while still being substantially planar.

The appendages 152 extend from the substantially planar body 150 of the thermally conductive structure 132 past the printed circuit board 128 to the cooling unit 130. In this configuration, the appendages include a neck 162 and a head 164. The head 164 is wider than the neck 162 and is shaped to engage a portion of the cooling unit 130. On top of the head 164 is a heat transfer surface 166 disposed adjacent a cooling surface 168 of the cooling unit 130.

As shown, the substantially planar body 150 includes a fluid chamber 154 extending into the substantially planar body 150 and the appendages 152. In this configuration, the fluid chamber 154 extends from one appendage 152 through the substantially planar body 150 and into a second appendage 152. The second appendage 152 extends from the substantially planar body 150 separately from the first appendage 152.

The fluid chamber 154 may be permanently sealed and contains a working fluid 156 that is a two-phase working fluid that has a liquid phase 158 and a vapor phase 160. Within the heads 164 of the appendages 152, the fluid chamber 154 expands to form a condensation portion 170 of the the fluid chamber 154. In some configurations, a condensation structure 172 may be positioned within the condensation portion 170. The condensation structure 172 is a structure that facilitates the condensation of the working fluid 156 into the liquid phase and conduction of heat through the heat transfer surface 166 to the adjacent cooling surface 168 of the cooling unit 130. As shown, the cooling fluid conduit 146 is positioned proximate the appendage 152 to facilitate cooling of the head 164 and the condensation portion 170. The thermally conductive material 142 is disposed between the cooling unit 130 and the appendage 152 to ensure good thermal conduction between the appendage 152 and the cooling unit 130. The condensation structure 172 may be a wicking mesh, perforated and/or sintered structure, fins, ribs, surface coating, etching, or combination thereof within the condensation portion 170 of the the fluid chamber 154.

As the working fluid 156 receives heat from the bottom surface electrical components 138, the liquid phase 158 of the working fluid 156 boils and vaporizes to become the vapor phase 160. The higher temperature vapor phase 160 rises and contacts the condensation portion 170 of the fluid chamber 154. In the condensation portion 170, heat is transferred from the vapor phase 160 to the heat transfer surface 166 and the vapor phase 160 of the working fluid 156 condenses into the liquid phase 158 and falls back to the liquid phase 158 of the working fluid 156 located in the substantially planar body 150 portion of the fluid chamber 154.

The working fluid 156 may have a boiling temperature greater than about 30 degrees Celsius at 1 atmosphere of pressure but lower than 100 degrees Celsius at 1 atmosphere of pressure. In some applications, the working fluid 156 in a liquid phase 158 fills at least 80% of a volume of the fluid chamber 154 when a temperature of the thermally conductive structure 132 and the working fluid 156 are about 22 degrees Celsius. In other applications, the working fluid 156 in the liquid phase 158 fills at least 60% of a volume of the fluid chamber 154 when the temperature of the thermally conductive structure 132 and the working fluid 156 are about 22 degrees Celsius. In yet others, the working fluid 156 in a liquid phase 158 filling less than 50% of a volume of the fluid chamber 154 when temperature of the thermally conductive structure 132 and the working fluid 156 are about 22 degrees Celsius. Further, in some applications, the working fluid 156, in a liquid phase 158, fills less than 25% of a volume of the fluid chamber when a temperature of the thermally conductive structure and the working fluid are about 22 degrees Celsius at atmospheric pressure or less than 22 degrees Celsius if below atmospheric pressure.

As shown in this configuration of the cooling system 100, the cooling unit 130 and thermally conductive structure 132 add relatively little to the combined height of the top surface electrical components 134, bottom surface electrical components 138, and the printed circuit board 128. In some embodiments, the combined height may be less than 30 mm. For example, less than 5 mm may be added to the bottom surface and/or less than 25 mm may be added to the top surface. In some embodiments, the cooling unit 130 does not include external fins for air cooling. Further, the cooling unit 130 may be substantially planar in its shape over the printed circuit board 128. Additionally, the substantially planar body 150 of the thermally conductive structure 132 includes a generally flat outside surface 174 positioned furthest from the cooling unit 130. The thermally conductive structure 132 does not include fins extending away from the generally flat outside surface 174 for air cooling. Consequently, the substantially planar body 150 may have a thickness of less than 5 mm. In some configurations, the substantially planar body 150 may have a thickness of less than 3 mm. In other configurations, the substantially planar body 150 may have a thickness of less than 2 mm. Thus, the cooling system 100 may add less than 10 mm to the overall height of the server 102.

FIG. 3 is a side view of a schematic diagram of a cooling system 200 without electrical components and a printed circuit board (not shown) according to one or more embodiments. The cooling system 200 includes a cooling unit 230 and a thermally conductive structure 232. The cooling system 200 includes an external connection port 214, a frame 244, a cooling fluid conduit 246, and cooling fluid 248.

The thermally conductive structure 232 includes a substantially planar body 250, a first appendage 252 and a separate second appendage 253. The first appendage 252 and the second appendage 253 extend from the substantially planar body 250 of the thermally conductive structure 232 across a gap 276 to the cooling unit 230 for thermal conduction with the cooling unit 230. The gap 276 is sized to receive a printed circuit board and attached components (not shown).

The first appendage 252 extends from the substantially planar body proximate an edge 278 of the substantially planar body 250. The second appendage 253 extends from the substantially planar body 250 at a position opposite the first appendage 252 across a surface 274 of the substantially planar body 250.

The thermally conductive structure 232 also includes a fluid chamber 254 containing a convection fluid 256. The fluid chamber 254 extends into the substantially planar body 250 and the first appendage 252 and the second appendage 253. This configuration relies on conduction and convection within the convection fluid 256 within the fluid chamber 254 to move a higher temperature convection fluid 260 into the first appendage 252 and the second appendage 253 and to move a cooler convection fluid 258 into the substantially planar body 250. As the higher temperature convection fluid 260 reaches heads 264 of the first appendage 252 and the second appendage 253, the cooling unit 230 draws away heat into the cooling fluid 248 cooling the higher temperature convection fluid 260 to become cooler convection fluid 258. In this embodiment, the convection fluid 256 is a fluid that changes density with temperature, specifically higher temperature convection fluid 260 is less dense than the cooler convection fluid 258. An example of convection fluid 256 is water and water based coolants.

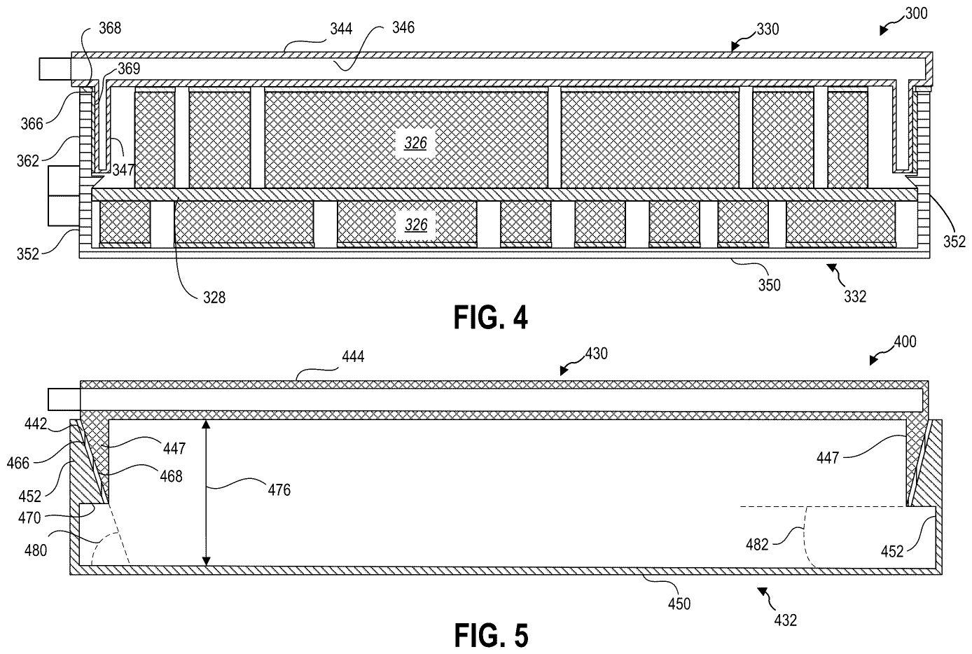

FIG. 4 is a side view of a schematic diagram of a cooling system 300 containing a printed circuit board 328 and attached electrical components 326 according to one or more embodiments. As shown, the cooling system 300 includes a cooling unit 330 and a thermally conductive structure 332. The thermally conductive structure 332 includes appendages 352 and a substantially planar body 350. The appendages 352 extend from the substantially planar body 350 toward the cooling unit 330. In this configuration, the thermally conductive structure 332 is made of a material with high thermal conductivity. For example, the thermally conductive structure 332 may be made of copper or silver.

The cooling unit 330 includes a frame 344 and a cooling fluid conduit 346. The frame 344 and the cooling fluid conduit 346 cooperate to form a cooling extension 347 that extends down toward the thermally conductive structure 332. The cooling unit 330 further includes a first cooling surface 368 that is positioned closest to a top surface 366 of the appendage 352. A vertically oriented second cooling surface 369 of the cooling extension 347 is disposed adjacent a neck 362 of the appendage 352. Consequently, the surface area between the cooling unit 330 and the thermally conductive structure 332 may be larger than other configurations as it covers the first cooling surface 368 and second cooling surface 369. This may increase the heat transferred to the cooling unit 330 from the thermally conductive structure 332.

FIG. 5 is a side view of a schematic diagram of a cooling system 400 according to one or more embodiments. In this configuration, the cooling system 400 includes cooling unit 430 and a thermally conductive structure 432. The thermally conductive structure 432 includes appendages 452 and a substantially planar body 450. The appendages 452 extend from the substantially planar body 450 toward the cooling unit 430. In this configuration, the thermally conductive structure 432 is also made of a material with high thermal conductivity.

The cooling unit 430 includes a cooling extension 447 extending down from a frame 444 of the cooling unit 430 toward the thermally conductive structure 432 that is also made of a material with high thermal conductivity. The appendages 452 include a heat transfer surface 466 that is positioned adjacent a cooling surface 468 of the cooling extension 447. A conductive material 442 may be placed between the heat transfer surface 466 and the cooling surface 468.

The heat transfer surface 466 extends at an angle 480 to the substantially planar body 450 ranging between about 0 degrees to about 90 degrees. In some configurations, the heat transfer surface 466 may extend at the angle 480 to the substantially planar body 450 ranging between 10 degrees to about 80 degrees. In others, the heat transfer surface 466 may extend at the angle 480 to the substantially planar body 450 ranging between 30 degrees to about 60 degrees.

The appendages 452 also include a retention surface 470 positioned to abut a printed circuit board (not shown) positioned within a gap 476. The retention surface 470 may be used to retain the position of the printed circuit board a relative to the thermally conductive structure 432. The retention surface is disposed at an angle 482 to the substantially planar body 450 of the thermally conductive structure. The angle 482 may range from −45 degrees to 45 degrees. As shown in this configuration, the angle 482 is 0 degrees since it is substantially parallel to the substantially planar body 450.

A problem may arise if the printed circuit board moves relative to the thermally conductive structure 432 because it may disturb a thermally conductive material 442 when placed between the bottom surface electrical components of the printed circuit board and the thermally conductive structure 432 (as shown in FIG. 2). If disturbed, the thermal connection may weaken, preventing the efficient conduction of heat from the electrical components to the thermally conductive structure 432.

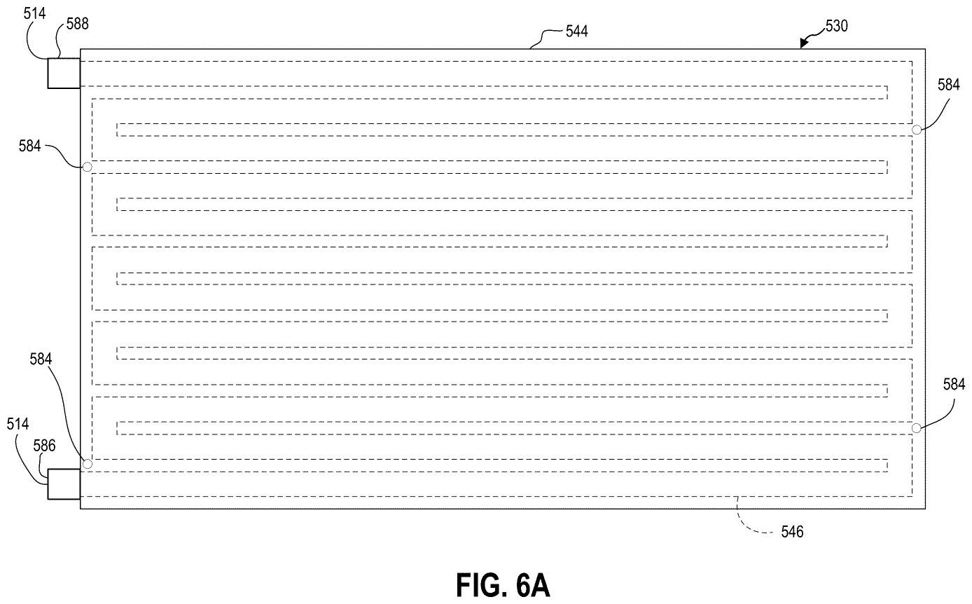

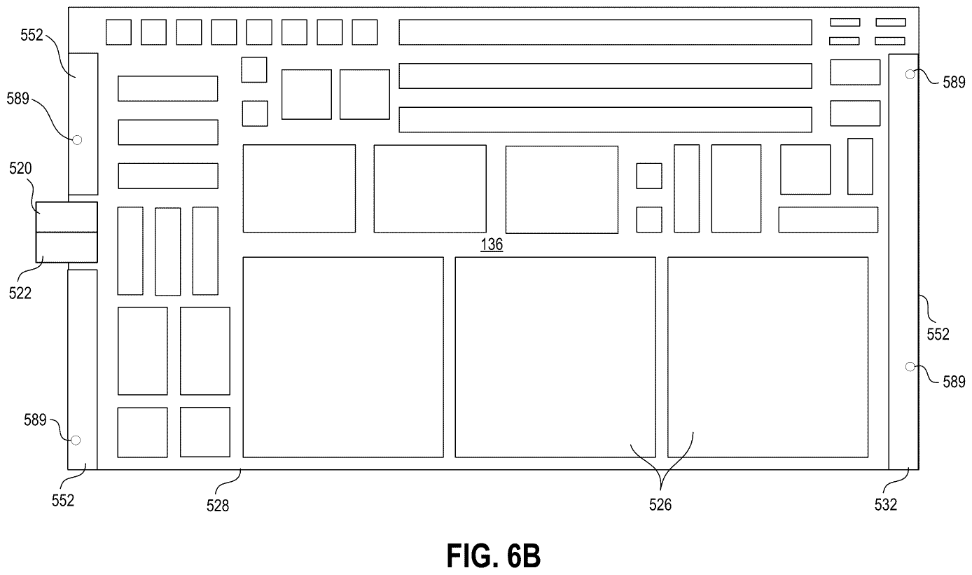

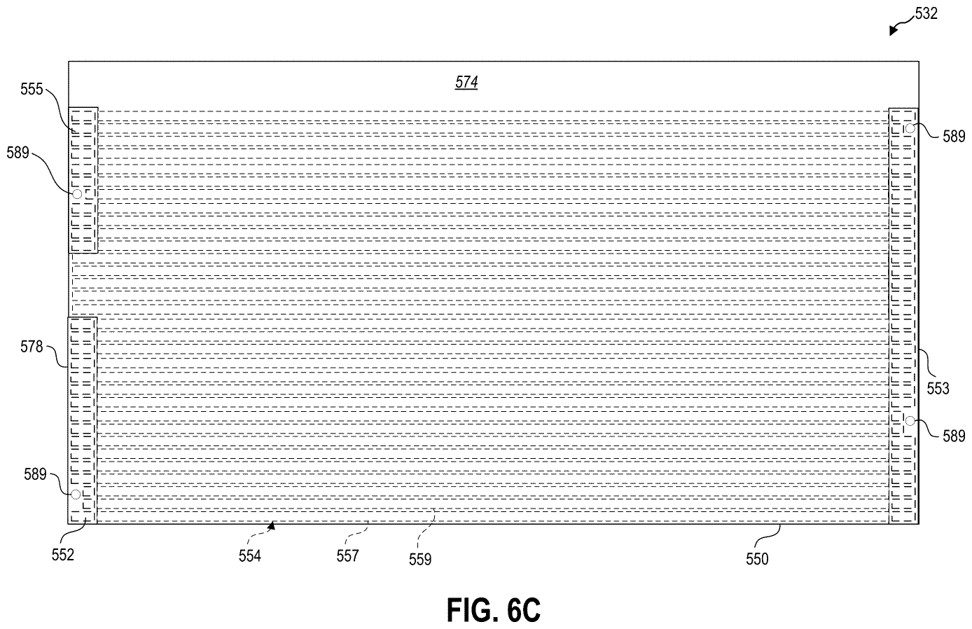

FIG. 6A is a top view of a schematic diagram of a cooling unit 530 of a cooling system according to one or more embodiments. As shown, the cooling unit 530 includes external connection ports 514, a frame 544, a cooling fluid conduit 546, and attachment features 584. The external connection ports 514 include an inlet 586 and an outlet 588 in fluid communication with the cooling fluid conduit 546. As noted above, the external connection ports 514 may be quick disconnect, a threaded connection, and may include a valve to prevent the loss of cooling fluid from the cooling fluid conduit 546.

The frame 544 may be a unitary design having an integrally formed cooling fluid conduit 546 or an assembly built around the cooling fluid conduit 546. The frame 544 is made of materials having a high thermal conductivity.

The attachment features 584 are holes for receiving threaded fasteners. The attachment features 584 permit the cooling unit 530 to be attached and secured to the thermally conductive structure 532 (shown in FIG. 6B).

FIG. 6B is a top view of a schematic diagram of a printed circuit board 528 positioned on the thermally conductive structure 532 according to one or more embodiments. As shown, an electrical connector 520, a data connector 522, and electrical components 526 are mounted on a top surface 136 of the printed circuit board 528. Appendages 552 of the thermally conductive structure 532 are positioned adjacent the printed circuit board 528 and include attachment features 589. The attachment features 589 are holes for receiving threaded fasteners. The attachment features 589 permit the thermally conductive structure 532 to be attached and secured to the cooling unit 530 shown in FIG. 6A.

FIG. 6C is a top view of a schematic diagram of the thermally conductive structure 532. The thermally conductive structure 532 includes a substantially planar body 550 and a first appendage 552, a second appendage 553, and a third appendage 555. The first appendage 552 extends upward from the substantially planar body 550 proximate an edge 578 of the substantially planar body 550. The second appendage 553 extends upward from the substantially planar body 550 at a position opposite the first appendage 552 across a surface 574 of the substantially planar body 550. The first appendage 552, the second appendage 553, and the third appendage 555 includes an attachment feature 589 to facilitate mechanical attachment to the cooling unit 530 shown in FIG. 6A. As shown in dotted lines, a plurality of fluid chambers 554 extend through the substantially planar body 550. The plurality of fluid chambers 554 contains a two-phase working fluid. The working fluid in a liquid phase may fill less than 50% of the volume of the plurality of fluid chambers 554 when temperature of the thermally conductive structure 532 and the working fluid are about 22 degrees Celsius. In some applications, the working fluid in a liquid phase fills less than 25% of the volume of the plurality of fluid chambers 554 when temperature of the thermally conductive structure and the working fluid are about 22 degrees Celsius.

As an example of the plurality of fluid chambers 554, a first fluid chamber 557 extends into the first appendage 552, through the substantially planar body 550, and into the second appendage 553. A second fluid chamber 559 extends parallel to the first fluid chamber 557. The second fluid chamber 559 also extends into the first appendage 552, through the substantially planar body 550, and into the second appendage 553.

When an electrical component operates that is mounted on a bottom surface of the printed circuit board 528 (shown in FIG. 6B) and is thermally connected to the thermally conductive structure 532, the electrical component generates heat that is conducted into the thermally conductive structure 532 and the working fluid in the first fluid chamber 557 and the second fluid chamber 559.

As the working fluids in the first fluid chamber 557 and second fluid chamber 559 separately heat, the working fluids are converted into a vapor phase that moves by convection through the first fluid chamber 557 and second fluid chamber 559 respectively up into one of the first appendage 552 or the second appendage 553. As the vapor moves up into one of the first appendage 552 or the second appendage 553, the heat in the vapor is conducted into the thermally connected cooling unit 530 (shown in FIG. 6A). When enough heat is conducted away, the vapor condenses into a liquid phase of the cooling fluid and moves back down into the substantially planar body 550 to repeat the cycle.

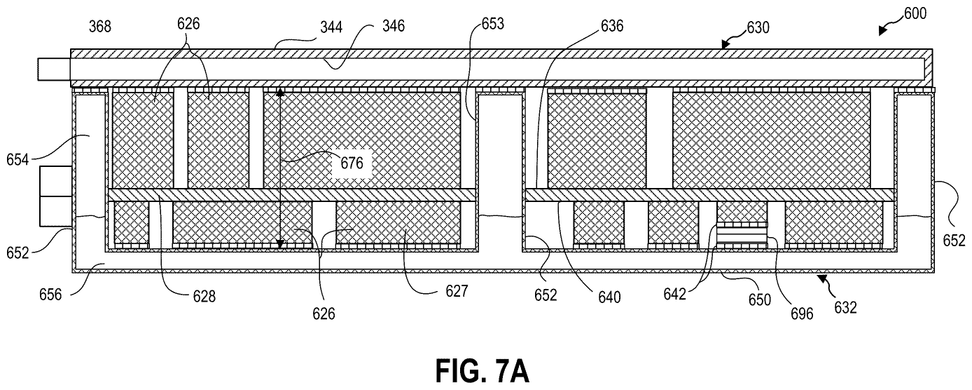

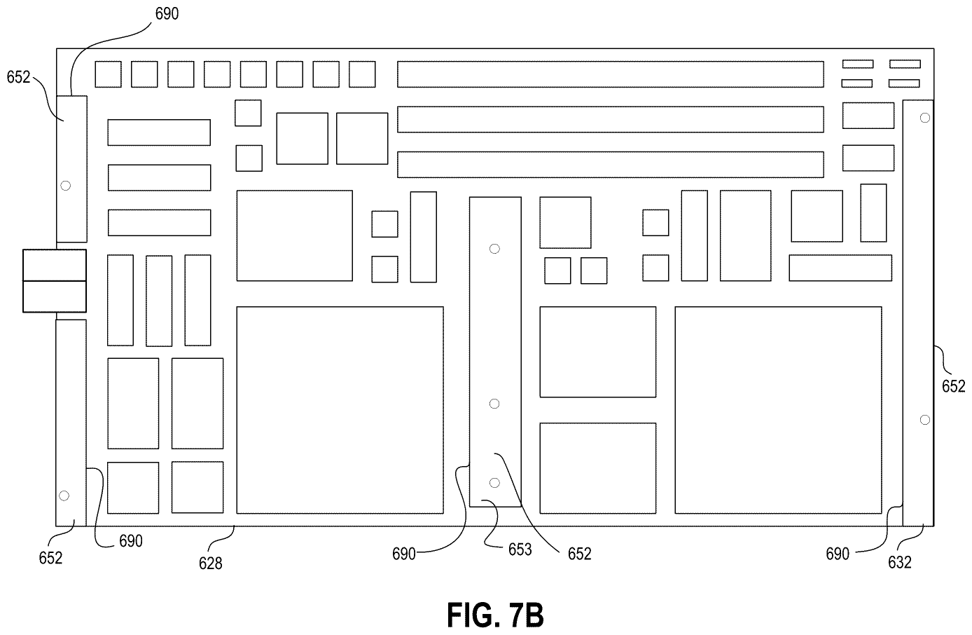

FIG. 7A is a side view of a schematic diagram of a cooling system 600 according to one or more embodiments. In this configuration, the cooling system 600 includes a cooling unit 630 mounted above a thermally conductive structure 632. The thermally conductive structure 632 includes a substantially planar body 650 and a plurality of appendages 652 extending up from the substantially planar body 650 to the cooling unit 630.

As shown, a printed circuit board 628 is disposed in the gap 676 between the cooling unit 630 and the thermally conductive structure 632. A plurality of electrical components 626 are attached to a top surface 636 and a bottom surface 640 of the printed circuit board 628. A first appendage 653 of the plurality of appendages 652 may be positioned in a central location to provide additional cooling for electrical components 626 near the middle of a printed circuit board 628. In some configurations, the first appendage 653 is positioned adjacent a highest powered electrical component 627 of the electrical components 626 attached to the bottom surface 640 of the printed circuit board 628.

A single fluid chamber 654 extends through the substantially planar body 650 and the appendages 652. A two phase working fluid 656 is disposed in the fluid chamber 654.

FIG. 7B is a top view of a schematic diagram of the printed circuit board 628 positioned on the thermally conductive structure 632 according to one or more embodiments. In this configuration, the printed circuit board 628 may include cutouts 690 that permit the appendages 652 to extend through the printed circuit board 628. The cutouts 690 may assist in retaining the printed circuit board 628 in position relative to the cooling system 600. As shown, the first appendage 653 of the plurality of appendages 652 is positioned in a central location to provide additional cooling for bottom surface electrical components near the middle of a printed circuit board. The first appendage 653 may be positioned near or adjacent critical or high powered components to facilitate the transfer of thermal load to the cooling unit 630 (shown in FIG. 7A). In some applications, the first appendage 653 is positioned adjacent a highest powered electrical component of the electrical components attached to the bottom surface of the printed circuit board.

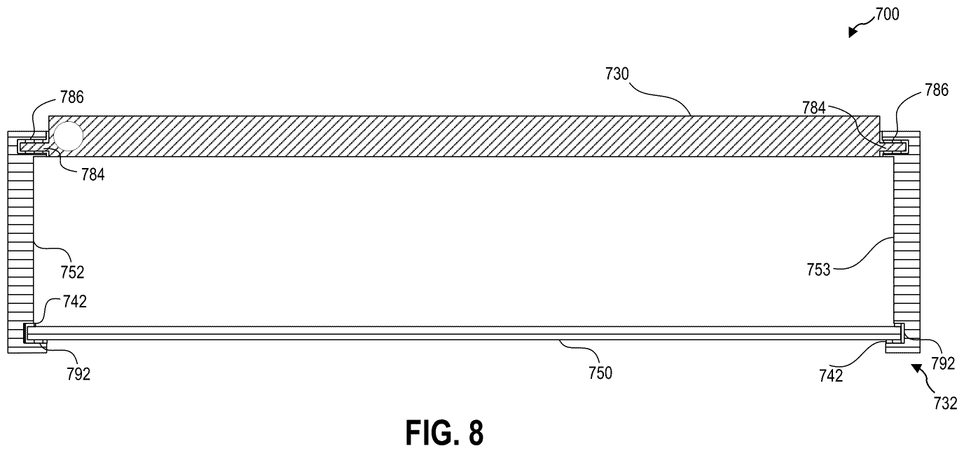

FIG. 8A is a side view of a schematic diagram of a cooling system 700 according to one or more embodiments. The cooling system 700 includes a cooling unit 730 and a thermally conductive structure 732. The cooling system 700 includes attachment features 784. The attachment features 784 are tabs that are inserted into reciprocal attachment features 786 of the thermally conductive structure 732. The thermally conductive structure 732 includes a substantially planar body 750, a first appendage 752, and a second appendage 753. The reciprocal attachment features 786 are disposed in the first appendage 752 and the second appendage 753. The attachment features 784 and reciprocal attachment features 786 may also be attached together by mechanical fasteners (not shown).

As shown, the substantially planar body 750 is separable from the first appendage 752 and the second appendage 753. The substantially planar body 750 is connected to the first appendage 752 and the second appendage 753 at body attachment features 792. A thermally conductive material 742 is placed between the first appendage 752 and the substantially planar body 750, and between the second appendage 753 and the substantially planar body 750.

This separable version of the thermally conductive structure 732 may be used with fluid chambers disposed within the substantially planar body 750 and/or the first appendage 752 and/or the second appendage 753. Further, this configuration provides the advantage of allowing the appendages to be selectively placed at locations adjacent a highest powered electrical component of the electrical components attached to the bottom surface of printed circuit board.

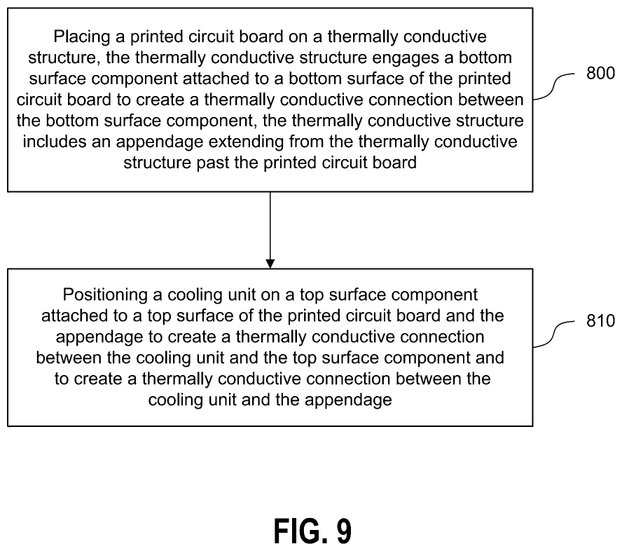

FIG. 9 is a flow chart illustrating a method according to at least one embodiment of the present disclosure. The method includes placing a printed circuit board on a thermally conductive structure at 800. The thermally conductive structure engages a bottom surface component attached to a bottom surface of the printed circuit board to create a thermally conductive connection between the bottom surface component and thermally conductive structure. The thermally conductive structure includes an appendage extending from the thermally conductive structure past the printed circuit board. The method further includes positioning a cooling unit on a top surface component attached to a top surface of the printed circuit board and the appendage to create a thermally conductive connection between the cooling unit and the top surface component and to create a thermally conductive connection between the cooling unit and the appendage at 810.

Embodiments of the present disclosure may thus utilize a special purpose or general-purpose computing system including computer hardware, such as, for example, one or more processors and system memory. Embodiments within the scope of the present disclosure also include physical and other computer-readable media for carrying or storing computer-executable instructions and/or data structures, including applications, tables, data, libraries, or other modules used to execute particular functions or direct selection or execution of other modules. Such computer-readable media may be any available media that may be accessed by a general purpose or special purpose computer system. Computer-readable media that store computer-executable instructions (or software instructions) are physical storage media. Computer-readable media that carry computer-executable instructions are transmission media. Thus, by way of example, and not limitation, embodiments of the present disclosure may include at least two distinctly different kinds of computer-readable media, namely physical storage media or transmission media. Combinations of physical storage media and transmission media should also be included within the scope of computer-readable media.

### INDUSTRIAL APPLICABILITY

In general, systems and methods for cooling electrical components on a printed circuit board are disclosed. These systems and methods may save time and resources in removing a server from a server rack. Further, these systems and methods may occupy less space than other cooling systems and methods.
In aspect A1 of the disclosure, a system comprising: a cooling unit; and a thermally conductive structure defining a gap between the cooling unit and the thermal conductive structure, the thermally conductive structure including an appendage extending from the thermally conductive structure across the gap to the cooling unit for thermal conduction with the cooling unit, the gap sized to receive a printed circuit board and attached components.
A2. The system of aspects A1, further including a printed circuit board disposed in the gap, a plurality of electrical components attached to a top surface and a bottom surface of the printed circuit board, the appendage positioned adjacent a highest powered electrical component of the electrical components attached to the bottom surface of printed circuit board.
A3. The system of aspects A1 or A2, the thermally conductive structure includes a substantially planar body and a fluid chamber containing a working fluid, the fluid chamber extending in the substantially planar body.
A4. The system of aspects A1, A2, or A3, the thermally conductive structure includes a substantially planar body and a fluid chamber containing a working fluid, the fluid chamber extending in the the appendage.
A5. The system of aspects A1, A2, A3, or A4, a condensation structure is disposed within a portion of the fluid chamber disposed within the appendage.
A6. The system of aspects A1, A2, A3, A4, or A5, the thermally conductive structure includes a second fluid chamber extending in the substantially planar body, the second fluid chamber containing a second working fluid.
A7. The system of aspects A1, A2, A3, A4, A5, or A6, a boiling temperature of the working fluid is greater than about 30 degrees Celsius at 1 atmosphere of pressure but lower than 100 degrees Celsius at 1 atmosphere of pressure.
A8. The system of aspects A1, A2, A3, A4, A5, or A6, a working fluid is disposed in the fluid chamber, the working fluid in a liquid phase filling at least 60% of a volume of the fluid chamber when temperature of the thermally conductive structure and the working fluid are about 22 degrees Celsius.
A9. The system of aspects A1, A2, A3, A4, A5, or A6, wherein a working fluid is disposed in the fluid chamber, the working fluid in a liquid phase filling at least 80% of a volume of the fluid chamber when temperature of the thermally conductive structure and the working fluid are about 22 degrees Celsius.
A10. The system of aspects A1, A2, A3, A4, A5, or A6, wherein a working fluid is disposed in the fluid chamber, the working fluid in a liquid phase filling less than 50% of a volume of the fluid chamber when temperature of the thermally conductive structure and the working fluid are about 22 degrees Celsius.
A11. The system of aspects A1, A2, A3, A4, A5, or A6, wherein a working fluid is disposed in the fluid chamber, the working fluid in a liquid phase filling less than 25% of a volume of the fluid chamber when temperature of the thermally conductive structure and the working fluid are about 22 degrees Celsius.
A12. The system of aspects A1, A2, A3, A4, A5, A6, A7, A8, A9, A10, or A11, the appendage is a first appendage, the thermally conductive structure including a second appendage that extends from the thermally conductive structure separately from the first appendage.
A13. The system of aspects A1, A2, A3, A4, A5, A6, A7, A8, A9, A10, A11, or A12, the thermally conductive structure including a substantially planar body, the first appendage extending from the substantially planar body proximate an edge of the substantially planar body, the second appendage extending from the substantially planar body at a position opposite the first appendage across a surface of the substantially planar body.
A14. The system of aspects A1, A2, A3, A4, A5, A6, A7, A8, A9, A10, A11, A12, or A13, the appendage including a neck and a head, the head is wider than the neck and shaped to engage a portion of the cooling unit.
A15. The system of aspects A1, A2, A3, A4, A5, A6, A7, A8, A9, A10, A11, A12, A13, or A14, the cooling unit including an extension extending toward a substantially planar body of the thermally conductive structure from the cooling unit, the cooling extension including a cooling surface, the appendage including a heat transfer surface disposed adjacent to the cooling surface of the cooling unit.
A16. The system of aspects A15, the heat transfer surface extending at an angle to the substantially planar body ranging between about 0 degrees to about 90 degrees.
A17. The system of aspects A1, A2, A3, A4, A5, A6, A7, A8, A9, A10, A11, A12, A13, A14, A15, or A16, the thermally conductive structure includes a substantially planar body, the substantially planar body having a thickness of less than 5 mm.
A18. The system of aspects A1, A2, A3, A4, A5, A6, A7, A8, A9, A10, A11, A12, A13, A14, A15, or A16, the thermally conductive structure includes a substantially planar body, the substantially planar body having a thickness of less than 3 mm.
A19. The system of aspects A1, A2, A3, A4, A5, A6, A7, A8, A9, A10, A11, A12, A13, A14, A15, or A16, the thermally conductive structure includes a substantially planar body, the substantially planar body having a thickness of less than 2 mm.
A20. The system of aspects A1, A2, A3, A4, A5, A6, A7, A8, A9, A10, A11, A12, A13, A14, A15, A16, A17, A18, or A19, the thermally conductive structure including a generally flat outside surface positioned furthest from the cooling unit.
A21. The system of aspects A1, A2, A3, A4, A5, A6, A7, A8, A9, A10, A11, A12, A13, A14, A15, A16, A17, A18, A19, or A20, the thermally conductive structure does not include fins extending away from the generally flat outside surface.
A22. The system of aspects A1, A2, A3, A4, A5, A6, A7, A8, A9, A10, A11, A12, A13, A14, A15, A16, A17, A18, A19, A20, or A21, wherein the appendage is a first appendage, the thermally conductive structure further including a second appendage that extends from the thermally conductive structure across the gap to the cooling unit for thermal conduction with the cooling unit, the first appendage and the second appendage include an attachment feature to facilitate mechanical attachment to the cooling unit.
A23. The system of aspects A1, A2, A3, A4, A5, A6, A7, A8, A9, A10, A11, A12, A13, A14, A15, A16, A17, A18, A19, A20, A21, A22, or A23, the working fluid is a two-phase working fluid.
A24. The system of aspects A1, A2, A3, A4, A5, A6, A7, A8, A9, A10, A11, A12, A13, A14, A15, A16, A17, A18, A19, A20, A21, A22, or A23, the fluid chamber is permanently sealed.
A25. The system of aspects A1, A2, A3, A4, A5, A6, A7, A8, A9, A10, A11, A12, A13, A14, A15, A16, A17, A18, A19, A20, A21, A22, A23, or A24, the appendage including a retention surface disposed at an angle to a substantially planar body of the thermally conductive structure, the angle ranging from −45 degrees to 45 degrees, the retention surface positioned to abut the printed circuit board positioned within the gap.
A26. The system of aspects A1, A2, A3, A4, A5, A6, A7, A8, A9, A10, A11, A12, A13, A14, A15, A16, A17, A18, A19, A20, A21, A22, A23, A24, or A25, the cooling unit including a cooling fluid conduit positioned proximate the appendage.
A27. The system of aspects A1, A2, A3, A4, A5, A6, A7, A8, A9, A10, A11, A12, A13, A14, A15, A16, A17, A18, A19, A20, A21, A22, A23, A24, A25, or A26, the cooling unit including an external connection port fluidly connected to the cooling fluid conduit.
A28. The system of aspects A27, the external connection port is a quick disconnect.
A29. The system of aspects A1, A2, A3, A4, A5, A6, A7, A8, A9, A10, A11, A12, A13, A14, A15, A16, A17, A18, A19, A20, A21, A22, A23, A24, A25, A26, A27, or A28 wherein the thermally conductive structure is made of copper.
A30. The system of aspects A1, A2, A3, A4, A5, A6, A7, A8, A9, A10, A11, A12, A13, A14, A15, A16, A17, A18, A19, A20, A21, A22, A23, A24, A25, A26, A27, A28, or A29 further comprising a thermally conductive material disposed between the cooling unit and the appendage to permit heat to be thermally conducted from the appendage into the cooling unit.
A31. The system of aspects A1, A2, A3, A4, A5, A6, A7, A8, A9, A10, A11, A12, A13, A14, A15, A16, A17, A18, A19, A20, A21, A22, A23, A24, A25, A26, A27, A28, A29, or A30, the heat transfer surface extending at an angle to the substantially planar body ranging between 10 degrees to about 80 degrees.
A32. The system of aspects A1, A2, A3, A4, A5, A6, A7, A8, A9, A10, A11, A12, A13, A14, A15, A16, A17, A18, A19, A20, A21, A22, A23, A24, A25, A26, A27, A28, A29, or A30, the heat transfer surface extending at an angle to the substantially planar body ranging between 30degrees to about 60 degrees.
A33. The system of aspects A1, A2, A3, A4, A5, A6, A7, A8, A9, A10, A11, A12, A13, A14, A15, A16, A17, A18, A19, A20, A21, A22, A23, A24, A25, A26, A27, A28, A29, A30, A31, or A32, the cooling unit does not include external fins.
A34. The system of aspects A1, A2, A3, A4, A5, A6, A7, A8, A9, A10, A11, A12, A13, A14, A15, A16, A17, A18, A19, A20, A21, A22, A23, A24, A25, A26, A27, A28, A29, A30, A31, A32, or A33, the thermally conductive structure including a substantially planar body, the appendage and the substantially planar body being separable.
In aspect B1 of the disclosure, a method comprising: placing a printed circuit board on a thermally conductive structure, the thermally conductive structure engages a bottom surface component attached to a bottom surface of the printed circuit board to create a thermally conductive connection between the bottom surface component and thermally conductive structure, the thermally conductive structure includes an appendage extending from the thermally conductive structure past the printed circuit board; and positioning a cooling unit on a top surface component attached to a top surface of the printed circuit board and the appendage to create a thermally conductive connection between the cooling unit and the top surface component and to create a thermally conductive connection between the cooling unit and the appendage.
B2. The method of aspect B1, comprising placing a conductive material on the top surface component, wherein the conductive material is disposed between the top surface component and the cooling unit; and placing the conductive material on the bottom surface component wherein the conductive material is disposed between the bottom surface component and the thermally conductive structure.
B3. The method of aspects B1 or B2, comprising placing the conductive material on the appendage of the thermally conductive structure, wherein the conductive material is disposed between the appendage and the cooling unit.
B4. The method of aspects B1, B2, or B3, the cooling unit and the appendage include an attachment feature, the method comprising mechanically attaching the appendage to the cooling unit through use of the attachment features.
B5. The method of aspects B1, B2, B3, or B4, the cooling unit including cooling fluid conduit positioned proximate the appendage, the method comprising cooling the appendage by moving cooling fluid through the cooling fluid conduit.
B6. The method of aspects B1, B2, B3, B4, or B5, the cooling unit including an external connection port fluidly connected to the cooling fluid conduit, the method comprising connecting the cooling unit to a source of cooling fluid.
B7. The method of aspects B1, B2, B3, B4, B5, or B6, the external connection port is a quick disconnect.
B8. The method of aspects B1, B2, B3, B4, B5, B6, or B7, the thermally conductive structure includes a substantially planar body and a fluid chamber containing a working fluid, the fluid chamber extending into the substantially planar body and the appendage, the method comprising convecting the working fluid within the fluid chamber to move a higher temperature working fluid into the appendage and a cooler working fluid moves into the substantially planar body.
B9. The method of aspects B1, B2, B3, B4, B5, B6, B7, or B8, the thermally conductive structure includes a substantially planar body and a fluid chamber containing a working fluid, the fluid chamber extending into the substantially planar body and the appendage, the method comprising boiling the working fluid within the fluid chamber in the substantially planar body and condensing a vapor phase of the working fluid in the fluid chamber in the appendage.
B10. The method of aspects B1, B2, B3, B4, B5, B6, B7, B8, or B9, the condensing of a vapor phase occurs at a condensation structure disposed within a portion of the fluid chamber in the appendage.
B11. The method of aspects B1, B2, B3, B4, B5, B6, B7, B8, B9, or B10, the thermally conductive structure includes a second fluid chamber extending in the substantially planar body, the second fluid chamber containing the working fluid.
B12. The method of aspects B1, B2, B3, B4, B5, B6, B7, B8, B9, B10, or B11, the cooling unit including an extension extending toward the thermally conductive structure and positioned adjacent the appendage, the method including placing a conductive material between the extension and the appendage.
B13. The method of aspects B1, B2, B3, B4, B5, B6, B7, B8, B9, B10, B11, or B12, the thermally conductive structure including a substantially planar body, the appendage and the substantially planar body being separable, the method including connecting the appendage to the substantially planar body.
B14. The method of aspects B1, B2, B3, B4, B5, B6, B7, B8, B9, B10, B11, B12, or B13, the thermally conductive structure includes a substantially planar body, the substantially planar body having a thickness of less than 5 mm.
B15. The method of aspects B1, B2, B3, B4, B5, B6, B7, B8, B9, B10, B11, B12, or B13, the thermally conductive structure includes a substantially planar body, the substantially planar body having a thickness of less than 3 mm.
B16. The method of aspects B1, B2, B3, B4, B5, B6, B7, B8, B9, B10, B11, B12, or B13, the thermally conductive structure includes a substantially planar body, the substantially planar body having a thickness of less than 2 mm.
B17. The method of aspects B1, B2, B3, B4, B5, B6, B7, B8, B9, B10, B11, B12, B13, B14, B15, or B16, the appendage is a first appendage, the thermally conductive structure including a second appendage that extends from the thermally conductive structure separately from the first appendage.
B18. The method of aspects B1, B2, B3, B4, B5, B6, B7, B8, B9, B10, B11, B12, B13, B14, B15, B16, or B17, the thermally conductive structure including a substantially planar body, the first appendage extending from the substantially planar body proximate an edge of the substantially planar body, the second appendage extending from the substantially planar body at a position opposite the first appendage across a surface of the substantially planar body.
B19. The method of aspects B1, B2, B3, B4, B5, B6, B7, B8, B9, B10, B11, B12, B13, B14, B15, B16, B17, or B18, the appendage including a neck and a head, the head is wider than the neck and shaped to engage a portion of the cooling unit.
B20. The method of aspects B1, B2, B3, B4, B5, B6, B7, B8, B9, B10, B11, B12, B13, B14, B15, B16, B17, B18, or B19, the cooling unit including a first cooling surface that is positioned closest to a substantially planar body of the thermally conductive structure, the appendage extending past the first cooling surface, the appendage including a heat transfer surface disposed adjacent to a second cooling surface of the cooling unit.
B21. The method of aspects B20, the heat transfer surface extending at an angle to the substantially planar body ranging between about 0 degrees to about 90 degrees.
B22. The method of aspects B1, B2, B3, B4, B5, B6, B7, B8, B9, B10, B11, B12, B13, B14, B15, B16, B17, B18, B19, B20, or B21, the thermally conductive structure including a generally flat outside surface positioned furthest from the cooling unit.
B23. The method of aspects B1, B2, B3, B4, B5, B6, B7, B8, B9, B10, B11, B12, B13, B14, B15, B16, B17, B18, B19, B20, B21, or B22, the thermally conductive structure does not include fins extending from a bottom surface.
B24. The method of aspects B1, B2, B3, B4, B5, B6, B7, B8, B9, B10, B11, B12, B13, B14, B15, B16, B17, B18, B19, B20, B21, or B22, or B 23, the cooling unit does not include external fins.
B25. The method of aspects B1, B2, B3, B4, B5, B6, B7, B8, B9, B10, B11, B12, B13, B14, B15, B16, B17, B18, B19, B20, B21, B22, B23, or B24, the fluid chamber is permanently sealed.
B26. The method of aspects B1, B2, B3, B4, B5, B6, B7, B8, B9, B10, B11, B12, B13, B14, B15, B16, B17, B18, B19, B20, B21, B22, B23, B24, or B25, the appendage including a retention surface disposed at an angle to a substantially planar body of the thermally conductive structure, the angle ranging from −45 degrees to 45 degrees, the retention surface abutting the printed circuit board.
B27. The method of aspects B1, B2, B3, B4, B5, B6, B7, B8, B9, B10, B11, B12, B13, B14, B15, B16, B17, B18, B19, B20, B21, B22, B23, B24, B25, or B26, wherein the thermally conductive structure is made of copper.
B28. The method of aspects B1, B2, B3, B4, B5, B6, B7, B8, B9, B10, B11, B12, B13, B14, B15, B16, B17, B18, B19, B20, B21, B22, B23, B24, B25, B26, or B27, a boiling temperature of the working fluid is greater than about 30 degrees Celsius at 1 atmosphere of pressure but lower than 100 degrees Celsius at 1 atmosphere of pressure.
B29. The method of aspects B1, B2, B3, B4, B5, B6, B7, B8, B9, B10, B11, B12, B13, B14, B15, B16, B17, B18, B19, B20, B21, B22, B23, B24, B25, B26, B27, or B28, wherein a fluid is disposed in the fluid chamber, the fluid in a liquid phase filling at least 80% of a volume of the fluid chamber when temperature of the thermally conductive structure and the fluid are about 22 degrees Celsius.
B30. The method of aspects B1, B2, B3, B4, B5, B6, B7, B8, B9, B10, B11, B12, B13, B14, B15, B16, B17, B18, B19, B20, B21, B22, B23, B24, B25, B26, B27, or B28, the working fluid in a liquid phase filling at least 60% of a volume of the fluid chamber when a temperature of the thermally conductive structure and the working fluid are about 22 degrees Celsius.
B31. The method of aspects B1, B2, B3, B4, B5, B6, B7, B8, B9, B10, B11, B12, B13, B14, B15, B16, B17, B18, B19, B20, B21, B22, B23, B24, B25, B26, B27, or B28, wherein a working fluid is disposed in the fluid chamber, the working fluid in a liquid phase filling less than 50% of a volume of the fluid chamber when temperature of the thermally conductive structure and the working fluid are about 22 degrees Celsius.
B32. The method of aspects B1, B2, B3, B4, B5, B6, B7, B8, B9, B10, B11, B12, B13, B14, B15, B16, B17, B18, B19, B20, B21, B22, B23, B24, B25, B26, B27, or B28, wherein a working fluid is disposed in the fluid chamber, the working fluid in a liquid phase filling less than 25% of a volume of the fluid chamber when temperature of the thermally conductive structure and the working fluid are about 22 degrees Celsius.
B33. The method of aspects B1, B2, B3, B4, B5, B6, B7, B8, B9, B10, B11, B12, B13, B14, B15, B16, B17, B18, B19, B20, B21, B22, B23, B24, B25, B26, B27, B28, B29, B30, B31, or B32, the heat transfer surface extending at an angle to the substantially planar body ranging between 10 degrees to about 80 degrees.
B34. The method of aspects B1, B2, B3, B4, B5, B6, B7, B8, B9, B10, B11, B12, B13, B14, B15, B16, B17, B18, B19, B20, B21, B22, B23, B24, B25, B26, B27, B28, B29, B30, B31, B32, or B33, the heat transfer surface extending at an angle to the substantially planar body ranging between 30 degrees to about 60 degrees.
B35. The method of aspects B1, B2, B3, B4, B5, B6, B7, B8, B9, B10, B11, B12, B13, B14, B15, B16, B17, B18, B19, B20, B21, B22, B23, B24, B25, B26, B27, B28, B29, B30, B31, B32, B33, or B34, further including placing a conductive material between the appendage and the substantially planar body.
B36. The method of aspects B1, B2, B3, B4, B5, B6, B7, B8, B9, B10, B11, B12, B13, B14, B15, B16, B17, B18, B19, B20, B21, B22, B23, B24, B25, B26, B27, B28, B29, B30, B31, B32, B33, B34, or B35, further including positioning the appendage adjacent a highest powered electrical component of the electrical components attached to the bottom surface of printed circuit board.
In aspect C1 of the disclosure, a server rack comprising: a power bus; a data connection; a cooling fluid manifold; and a server, the server connected to the power bus, the data connection, and the cooling fluid manifold, the server including: a cooling unit including a cooling fluid conduit and an external connection port fluidly connected to the cooling fluid conduit, the external connection port connected to the cooling fluid manifold; a printed circuit board including a top surface and a bottom surface, printed circuit board electrically connected to the power bus and the data connection; a plurality of electrical components attached to the top surface and the bottom surface of the printed circuit board; and a thermally conductive structure including a substantially planar body and an appendage extending from the substantially planar body across the printed circuit board to the cooling unit for thermal conduction with the cooling unit.
C2. The server rack of aspect C1, the thermally conductive structure includes a fluid chamber containing a working fluid, the fluid chamber extending into the substantially planar body and the appendage.
C3. The server rack of aspects C1 or C2, a condensation structure is disposed within a portion of the fluid chamber disposed within the appendage.
C4. The server rack of aspects C1, C2, or C3, the thermally conductive structure includes a second fluid chamber extending in the substantially planar body, the second fluid chamber containing a second working fluid.
C5. The server rack of aspects C1, C2, C3, or C4, the appendage is a first appendage, the thermally conductive structure including a second appendage that extends from the thermally conductive structure separately from the first appendage.
C6. The server rack of aspects C1, C2, C3, C4, or C5, the thermally conductive structure including a substantially planar body, the first appendage extending from the substantially planar body proximate an edge of the substantially planar body, the second appendage extending from the substantially planar body at a position opposite the first appendage across a surface of the substantially planar body.
C7. The server rack of aspects C1, C2, C3, C4, C5, or C6, the appendage including a neck and a head, the head is wider than the neck and shaped to engage a portion of the cooling unit.
C8. The server rack of aspects C1, C2, C3, C4, C5, C6, or C7, the cooling unit including a first cooling surface that is positioned closest to a substantially planar body of the thermally conductive structure, the appendage extending past the first cooling surface, the appendage including a heat transfer surface disposed adjacent to a second cooling surface of the cooling unit.
C9. The server rack of aspects C1, C2, C3, C4, C5, C6, C7, or C8, the heat transfer surface extending at an angle to the substantially planar body ranging between about 0 degrees to about 90 degrees.
C10. The server rack of aspects C1, C2, C3, C4, C5, C6, C7, C8, or C9, the thermally conductive structure includes a substantially planar body, the substantially planar body having a thickness of less than 5 mm.
C11. The server rack of aspects C1, C2, C3, C4, C5, C6, C7, C8, or C9, the thermally conductive structure includes a substantially planar body, the substantially planar body having a thickness of less than 3 mm.
C12. The server rack of aspects C1, C2, C3, C4, C5, C6, C7, C8, or C9, the thermally conductive structure includes a substantially planar body, the substantially planar body having a thickness of less than 2 mm.
C13. The server rack of aspects C1, C2, C3, C4, C5, C6, C7, C8, C9, C10, C11, or C12, the thermally conductive structure including a generally flat outside surface positioned furthest from the cooling unit.
C14. The server rack of aspects C1, C2, C3, C4, C5, C6, C7, C8, C9, C10, C11, C12, or C13, the thermally conductive structure does not include fins extending away from the generally flat outside surface.
C15. The server rack of aspects C1, C2, C3, C4, C5, C6, C7, C8, C9, C10, C11, C12, or C14, wherein the appendage is a first appendage, the thermally conductive structure further including a second appendage that extends from the thermally conductive structure across the printed circuit board to the cooling unit for thermal conduction with the cooling unit, the first appendage and the second appendage include an attachment feature to facilitate mechanical attachment to the cooling unit.
C16. The server rack of aspects C1, C2, C3, C4, C5, C6, C7, C8, C9, C10, C11, C12, C13, C14, or C15, the working fluid is a two-phase working fluid.
C17. The server rack of aspects C1, C2, C3, C4, C5, C6, C7, C8, C9, C10, C11, C12, C13, C14, C15, or C16, the fluid chamber is permanently sealed.
C18. The server rack of aspects C1, C2, C3, C4, C5, C6, C7, C8, C9, C10, C11, C12, C13, C14, C15, C16, or C17, the appendage including a retention surface disposed at an angle to a substantially planar body of the thermally conductive structure, the angle ranging from −45 degrees to 45 degrees, the retention surface positioned to abut the printed circuit board.
C19. The server rack of aspects C1, C2, C3, C4, C5, C6, C7, C8, C9, C10, C11, C12, C13, C14, C15, C16, C17, or C18, the cooling unit including a cooling fluid conduit positioned proximate the appendage.
C20. The server rack of aspects C1, C2, C3, C4, C5, C6, C7, C8, C9, C10, C11, C12, C13, C14, C15, C16, C17, C18, or C19, the cooling unit including an external connection port fluidly connected to the cooling fluid conduit.
C21. The server rack of aspects C20, the external connection port is a quick disconnect.
C22. The server rack of aspects C1, C2, C3, C4, C5, C6, C7, C8, C9, C10, C11, C12, C13, C14, C15, C16, C17, C18, C19, C20, or C21, wherein the thermally conductive structure is made of copper.
C23. The server rack of aspects C1, C2, C3, C4, C5, C6, C7, C8, C9, C10, C11, C12, C13, C14, C15, C16, C17, C18, C19, C20, C21, or C22, a boiling temperature of the working fluid is greater than about 30 degrees Celsius at 1 atmosphere of pressure but lower than 100 degrees Celsius at 1 atmosphere of pressure.
C24. The server rack of aspects C1, C2, C3, C4, C5, C6, C7, C8, C9, C10, C11, C12, C13, C14, C15, C16, C17, C18, C19, C20, C21, C22, or C23, wherein a working fluid is disposed in the fluid chamber, the working fluid in a liquid phase filling at least 80% of a volume of the fluid chamber when temperature of the thermally conductive structure and the working fluid are about 22 degrees Celsius.
C25. The server rack of aspects C1, C2, C3, C4, C5, C6, C7, C8, C9, C10, C11, C12, C13, C14, C15, C16, C17, C18, C19, C20, C21, C22, or C23, a working fluid is disposed in the fluid chamber, the working fluid in a liquid phase filling at least 60% of a volume of the fluid chamber when temperature of the thermally conductive structure and the working fluid are about 22 degrees Celsius.
C26. The server rack of aspects C1, C2, C3, C4, C5, C6, C7, C8, C9, C10, C11, C12, C13, C14, C15, C16, C17, C18, C19, C20, C21, C22, or C23, wherein a working fluid is disposed in the fluid chamber, the working fluid in a liquid phase filling less than 50% of a volume of the fluid chamber when temperature of the thermally conductive structure and the working fluid are about 22 degrees Celsius.
C27. The server rack of aspects C1, C2, C3, C4, C5, C6, C7, C8, C9, C10, C11, C12, C13, C14, C15, C16, C17, C18, C19, C20, C21, C22, or C23, wherein a working fluid is disposed in the fluid chamber, the working fluid in a liquid phase filling less than 25% of a volume of the fluid chamber when temperature of the thermally conductive structure and the working fluid are about 22 degrees Celsius.
C28. The server rack of aspects C1, C2, C3, C4, C5, C6, C7, C8, C9, C10, C11, C12, C13, C14, C15, C16, C17, C18, C19, C20, C21, C22, C23, C24, C25, C26, or C27, further comprising a thermally conductive material disposed between the cooling unit and the appendage to permit heat to be thermally conducted from the appendage into the cooling unit.
C29. The server rack of aspects C1, C2, C3, C4, C5, C6, C7, C8, C9, C10, C11, C12, C13, C14, C15, C16, C17, C18, C19, C20, C21, C22, C23, C24, C25, C26, C27, or C28, the heat transfer surface extending at an angle to the substantially planar body ranging between 10 degrees to about 80 degrees.
C30. The server rack of aspects C1, C2, C3, C4, C5, C6, C7, C8, C9, C10, C11, C12, C13, C14, C15, C16, C17, C18, C19, C20, C21, C22, C23, C24, C25, C26, C27, or C28, the heat transfer surface extending at an angle to the substantially planar body ranging between 30 degrees to about 60 degrees.
C31. The server rack of aspects C1, C2, C3, C4, C5, C6, C7, C8, C9, C10, C11, C12, C13, C14, C15, C16, C17, C18, C19, C20, C21, C22, C23, C24, C25, C26, C27, C28, C29, or C30, the cooling unit does not include external fins.
C32. The server rack of aspects C1, C2, C3, C4, C5, C6, C7, C8, C9, C10, C11, C12, C13, C14, C15, C16, C17, C18, C19, C20, C21, C22, C23, C24, C25, C26, C27, C28, C29, C30, or C 31, the cooling unit and the thermally conductive structure add less than 10 mm to a total thickness of the server.
C33. The server rack of aspects C1, C2, C3, C4, C5, C6, C7, C8, C9, C10, C11, C12, C13, C14, C15, C16, C17, C18, C19, C20, C21, C22, C23, C24, C25, C26, C27, C28, C29, C30, C31, or C32, the cooling unit including an extension extending toward the thermally conductive structure and positioned adjacent the appendage.
C34. The server rack of aspects C1, C2, C3, C4, C5, C6, C7, C8, C9, C10, C11, C12, C13, C14, C15, C16, C17, C18, C19, C20, C21, C22, C23, C24, C25, C26, C27, C28, C29, C30, C31, C32, or C33, the thermally conductive structure including a substantially planar body, the appendage and the substantially planar body being separable.
C35. The server rack of aspects C1, C2, C3, C4, C5, C6, C7, C8, C9, C10, C11, C12, C13, C14, C15, C16, C17, C18, C19, C20, C21, C22, C23, C24, C25, C26, C27, C28, C29, C30, C31, C32, C33, or C34, the appendage positioned adjacent a highest powered electrical component of the electrical components attached to the bottom surface of printed circuit board.
C36. The server rack of aspect C1, C2, C3, C4, C5, C6, C7, C8, C9, C10, C11, C12, C13, C14, C15, C16, C17, C18, C19, C20, C21, C22, C23, C24, C25, C26, C27, C28, C29, C30, C31, C32, C33, C34, or C35, the server rack does not include an air moving system.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers'specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

1. A system comprising:
a cooling unit; and
a thermally conductive structure defining a gap between the cooling unit and the thermally conductive structure, the thermally conductive structure including an appendage extending from the thermally conductive structure across the gap to the cooling unit for thermal conduction with the cooling unit, the gap sized to receive a printed circuit board and attached components.

2. The system of claim 1, the thermally conductive structure includes a substantially planar body and a fluid chamber containing a working fluid, the fluid chamber extending into the substantially planar body and the appendage.

3. The system of claim 2, a condensation structure is disposed within a portion of the fluid chamber disposed within the appendage.

4. The system of claim 2, the thermally conductive structure includes a second fluid chamber extending in the substantially planar body, the second fluid chamber containing a second working fluid.

5. The system of claim 1, the appendage is a first appendage, the thermally conductive structure including a second appendage that extends from the thermally conductive structure separately from the first appendage.

6. The system of claim 5, the thermally conductive structure including a substantially planar body, the first appendage extending from the substantially planar body proximate an edge of the substantially planar body, the second appendage extending from the substantially planar body at a position opposite the first appendage across a surface of the substantially planar body.

7. The system of claim 1, the appendage including a neck and a head, the head is wider than the neck and shaped to engage a portion of the cooling unit.

8. The system of claim 1, the cooling unit including a cooling extension extending toward a substantially planar body of the thermally conductive structure from the cooling unit, the cooling extension including a cooling surface, the appendage including a heat transfer surface disposed adjacent to the cooling surface of the cooling unit.

9. The system of claim 1, the thermally conductive structure includes a substantially planar body, the substantially planar body having a thickness of less than 5 mm.

10. The system of claim 1, the thermally conductive structure including a generally flat outside surface positioned furthest from the cooling unit.

11. The system of claim 1, the thermally conductive structure does not include fins extending from a bottom surface of the the thermally conductive structure.

12. The system of claim 1, the cooling unit including an extension extending toward the thermally conductive structure and positioned adjacent the appendage.

13. The system of claim 1, the thermally conductive structure including a substantially planar body, the appendage and the substantially planar body being separable.

14. The system of claim 1, further including a printed circuit board disposed in the gap, a plurality of electrical components attached to a top surface and a bottom surface of the printed circuit board, the appendage positioned adjacent a highest powered electrical component of the electrical components attached to the bottom surface of printed circuit board.

15. A method comprising:
placing a printed circuit board on a thermally conductive structure, the thermally conductive structure engaging a bottom surface component attached to a bottom surface of the printed circuit board to create a thermally conductive connection between the bottom surface component and thermally conductive structure, the thermally conductive structure including an appendage extending from the thermally conductive structure past the printed circuit board; and
positioning a cooling unit on a top surface component attached to a top surface of the printed circuit board and the appendage to create a thermally conductive connection between the cooling unit and the top surface component and to create a thermally conductive connection between the cooling unit and the appendage.

16. The method of claim 15, the thermally conductive structure includes a substantially planar body and a fluid chamber containing a working fluid, the fluid chamber extending into the substantially planar body and the appendage, the method comprising boiling the working fluid within the fluid chamber in the substantially planar body and condensing a vapor phase of the working fluid in the fluid chamber in the appendage.

17. The method of claim 15, the cooling unit including a first cooling surface that is positioned closest to a substantially planar body of the thermally conductive structure, the appendage extending past the first cooling surface, the appendage including a heat transfer surface disposed adjacent to a second cooling surface of the cooling unit.

18. The method of claim 15, further including positioning the appendage adjacent a highest powered electrical component of the electrical components attached to the bottom surface of printed circuit board.

19. A server rack comprising:
a power bus;
a data connection;
a cooling fluid manifold; and
a server, the server connected to the power bus, the data connection, and the cooling fluid manifold, the server including:
a cooling unit including a cooling fluid conduit and an external connection port fluidly connected to the cooling fluid conduit, the external connection port connected to the cooling fluid manifold;
a printed circuit board including a top surface and a bottom surface, the printed circuit board electrically connected to the power bus and the data connection;
a plurality of electrical components attached to the top surface and the bottom surface of the printed circuit board; and
a thermally conductive structure including a substantially planar body and an appendage extending from the substantially planar body across the printed circuit board to the cooling unit for thermal conduction with the cooling unit.

20. The server rack of claim 19, the cooling unit and the thermally conductive structure add less than 10 mm to a total thickness of the server.
